(19) United States
(12) Patent Application Publication
(10) Pub. No.: US 2018/0030602 A1
(43) Pub. Date: Feb. 1, 2018

(54) FABRICATION METHOD OF STRONTIUM NIOBIUM OXYNITRIDE FILM HAVING SMALL CARRIER DENSITY AND ITS USE

(71) Applicant: Panasonic Corporation, Osaka (JP)

(72) Inventors: RYOSUKE KIKUCHI, Osaka (JP); TORU NAKAMURA, Osaka (JP); KAZUHITO HATO, Osaka (JP)

(21) Appl. No.: 15/627,493

(22) Filed: Jun. 20, 2017

(30) Foreign Application Priority Data
Jul. 28, 2016 (JP) 2016-148096

(51) Int. Cl. C25B 1/00; C23C 14/34; C23C 14/00; C25B 11/04; C25B 9/06; C23C 14/06; C25B 1/04

(52) U.S. Cl. CPC C25B 1/003; C23C 14/0676; C23C 14/3407; C23C 14/3457; C25B 1/04; C25B 11/0405; C25B 9/06; C23C 14/0036; C25B 11/0415; C25B 11/0447

(57) ABSTRACT

The present invention provides a method for growing a strontium niobium oxynitride film, the method comprising: (a) growing, on a strontium titanate substrate, by a sputtering method, the strontium niobium oxynitride film having carrier density of not more than 1×10¹⁸ cm⁻³. The spirit of the present invention includes: (I) strontium niobium oxynitride having carrier density not more than 1×10¹⁸ cm⁻³, (II) a strontium niobium oxynitride film having carrier density not more than 1×10¹⁸ cm⁻³, (III) a photosemiconductor substrate comprising the strontium niobium oxynitride film, (IV) a hydrogen generation device comprising the photosemiconductor substrate, and (V) a hydrogen generation method using the photosemiconductor substrate. The present invention provides a fabrication method of a strontium niobium oxynitride film having small carrier density and its use.

### BACKGROUND

### 1. Technical Field

The present invention relates to a fabrication method of a strontium niobium oxynitride film having small carrier density and its use.

### 2. Description of the Related Art

NPL1 discloses that strontium niobium oxynitride represented by the chemical formula SrNbO₂N absorbs light having a wavelength of not more than 700 nanometers. Strontium niobium oxynitride is one kind of a perovskite niobium oxynitride. Furthermore, NPL1 discloses a semiconductor photoelectrode fabrication method in which SrNbO₂N particles are deposited on a fluorine-doped tin oxide substrate by an electrophoretic deposition method. According to NPL1, the thus-fabricated semiconductor photoelectrode is irradiated with light to generate oxygen due to water splitting on the surface of the semiconductor photoelectrode.

NPL2 discloses a method for growing a SrNbO₃₋ₓNₓ film (0≦x≦1) by a pulse laser deposition method on a KTaO₃ single-crystal substrate having an orientation plane of a (100) plane. According to NPL2, the thus-grown SrNbO₃₋ₓNₓ film has carrier density of not less than 1×10²¹ cm⁻³.

NPL3 discloses a method for growing a SrTaO₃₋ₓNₓ film (0≦x≦1.2) by a pulse laser deposition method on a SrTiO₃ single-crystal substrate having an orientation plane of a (100) plane. NPL3 does not disclose the carrier density of the thus-grown SrTaO₃₋ₓNₓ film.

### CITATION LIST

NPL1: Kazuhiko Maeda et al, “SrNbO₂N as a Water-Splitting Photoanode with a Wide Visible-Light Absorption Band”, Journal of the American Chemical Society, vol. 133, pp. 12334-12337 (2011)

NPL2: Daichi Oka et. al., ‘Electric Transport Properties of Nb-based perovskite oxynitride epitaxial thin films“, Proceedings of The 61st Japan Society of Applied Physics Spring Meeting, 2014, 18p-E8-13, 06-149.

NPL3: Daichi Oka et. al., “Possible ferroelectricity in perovskite oxynitride SrTaO₂N epitaxial thin films”, Scientific Reports, Vol. 4, pp 4987 (2014)

### SUMMARY

An object of the present invention is to provide a fabrication method of a strontium niobium oxynitride film having small carrier density and its use.

The present invention provides a method for growing a strontium niobium oxynitride film, the method comprising:

(a) growing, on a strontium titanate substrate, by a sputtering method, the strontium niobium oxynitride film having carrier density of not more than 1×10¹⁸ cm⁻³.

The spirit of the present invention includes:

(I) strontium niobium oxynitride having carrier density not more than 1×10¹⁸ cm⁻³, and

(II) a strontium niobium oxynitride film having carrier density not more than 1×10¹⁸ cm⁻³.

The spirit of the present invention further includes:

(III) a photosemiconductor substrate comprising the strontium niobium oxynitride film,

(IV) a hydrogen generation device comprising the photosemiconductor substrate, and

(V) a hydrogen generation method using the photosemiconductor substrate.

The present invention provides a fabrication method of a strontium niobium oxynitride film having small carrier density and its use.

### BRIEF DESCRIPTION OF THE DRAWINGS

FIG. 1 shows a cross-sectional view of a semiconductor photoelectrode 100.

FIG. 2 is a graph showing an X-ray diffraction measurement result in the inventive example 1.

FIG. 3 is a graph showing an X-ray diffraction measurement result in the inventive example 2.

FIG. 4 shows a cross-sectional view of a hydrogen generation device comprising the semiconductor photoelectrode 100.

FIG. 5 shows a cross-sectional view of the semiconductor photoelectrode 100.

FIG. 6 is a graph showing an X-ray diffraction measurement result in the inventive example 3.

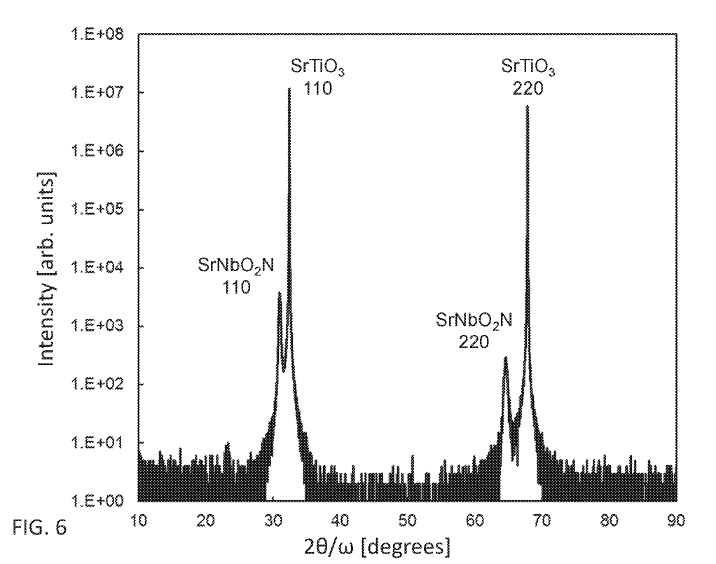

FIG. 7 is a graph showing an X-ray diffraction measurement result in the inventive example 4.

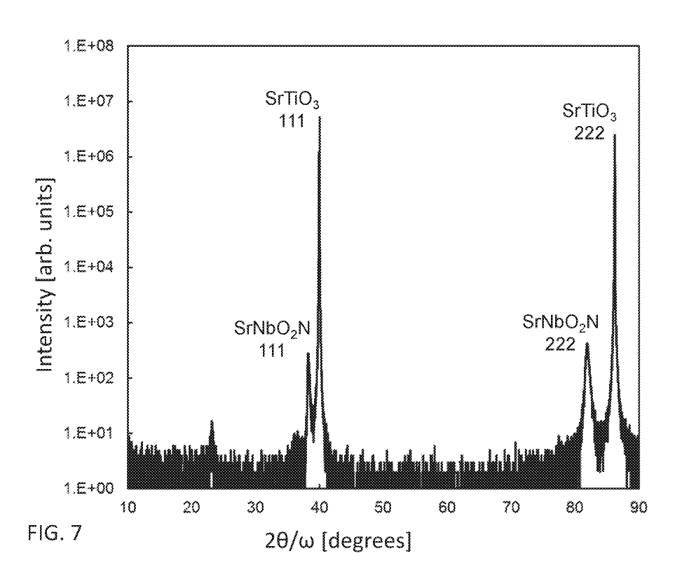

### DETAILED DESCRIPTION OF THE EMBODIMENT

Hereinafter, the embodiment of the present invention will be described with reference to the drawings.

(Embodiment)

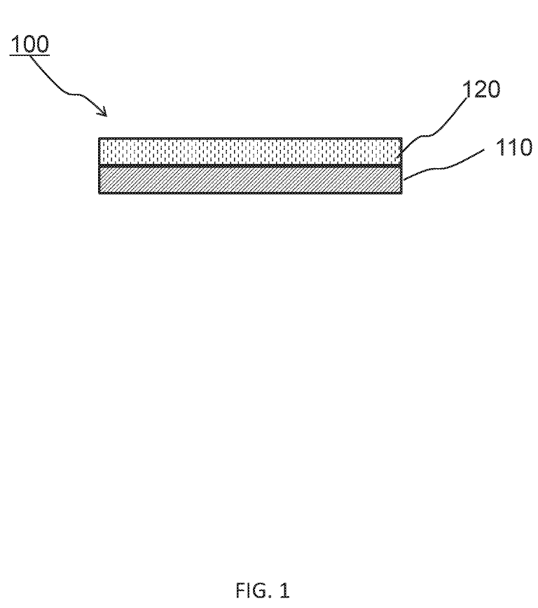

FIG. 1 shows a cross-sectional view of a semiconductor photoelectrode 100 according to the embodiment. The semiconductor photoelectrode 100 comprises a strontium titanate substrate 110 (hereinafter, referred to as “substrate 110”) and a strontium niobium oxynitride film 120. The substrate 110 may include another layer, as far as the surface of the substrate 110 is formed of strontium titanate. Desirably, the substrate 110 is single-crystal. The strontium titanate is represented by the chemical formula SrTiO₃. The strontium niobium oxynitride may be represented by the chemical formula SrNbO₃₋ₓNₓ (where x is more than 0 and not more than 3, desirably, x=1). The strontium niobium oxynitride is one kind of n-type semiconductors.

The strontium niobium oxynitride film 120 is formed on the surface of the substrate 110. Desirably, the strontium niobium oxynitride film 120 has an orientation plane. More preferably, the strontium niobium oxynitride film 120 has an orientation plane of a (001) plane.

(Fabrication Method)

A fabrication method according to the present embodiment will be described below.

While the temperature of the substrate 110 is maintained at not less than 500 degrees Celsius and not more than 750 degrees Celsius, the strontium niobium oxynitride film 120 is grown on the substrate 110. The substrate 110 is formed of strontium titanate, as described above. It is desirable that the substrate 110 is formed of single-crystal strontium titanate. It is desirable that the grown strontium niobium oxynitride film 120 has an orientation plane.

It is desirable that the substrate 110 has a principal surface of a (001) plane, a (110) plane, or a (111) plane. In other words, it is desirable that the surface of the substrate 110 formed of strontium titanate is oriented in a [001] direction, a [110] direction, or a [111] direction. It is more desirable that the substrate 110 comprises strontium titanate having only an (001) orientation plane, only an (110) orientation plane, or only an (111) orientation plane on the surface thereof.

The present inventors found that a strontium niobium oxynitride film grown by a sputtering method has significantly lower carrier density than a strontium niobium oxynitride film grown by a pulse laser deposition method. Specifically, the strontium niobium oxynitride film grown by a laser deposition method has high carrier density of not less than 1×10²¹ cm⁻³ (See NPL2), whereas the strontium niobium oxynitride film grown by a sputtering method has low carrier density of not more than 1×10¹⁸ cm⁻³, as demonstrated in the inventive examples which will be described later. In one embodiment, the strontium niobium oxynitride film grown by a sputtering method has low carrier density of not more than 1×10¹⁷ cm⁻³. As will be described later, the low carrier density improves hydrogen generation efficiency.

In the sputtering method, it is desirable that a target formed of strontium niobate represented by the chemical formula Sr₂Nb₂O₇ is used. Sputtering is carried out in an atmosphere of a mixture of argon and nitrogen. It is desirable that the atmosphere further contains oxygen. In this way, the strontium niobium oxynitride film 120 is grown on the substrate 110.

When the substrate 110 has an orientation plane of a (001) plane, the strontium niobium oxynitride film 120 also has an orientation plane of a (001) plane. It is more desirable that the strontium niobium oxynitride film 120 has a (001) orientation only. Likewise, when the substrate 110 has an orientation plane of a (110) plane, the strontium niobium oxynitride film 120 also has an orientation plane of a (110) plane. In this case, it is more desirable that the strontium niobium oxynitride film 120 has a (110) orientation only. When the substrate 110 has an orientation plane of a (111) plane, the strontium niobium oxynitride film 120 also has an orientation plane of a (111) plane. In this case, it is more desirable that the strontium niobium oxynitride film 120 has a (111) orientation only.

The strontium niobium oxynitride film 120 grown in this way has low carrier density of not more than 1.0×10¹³ cm⁻³, as described above.

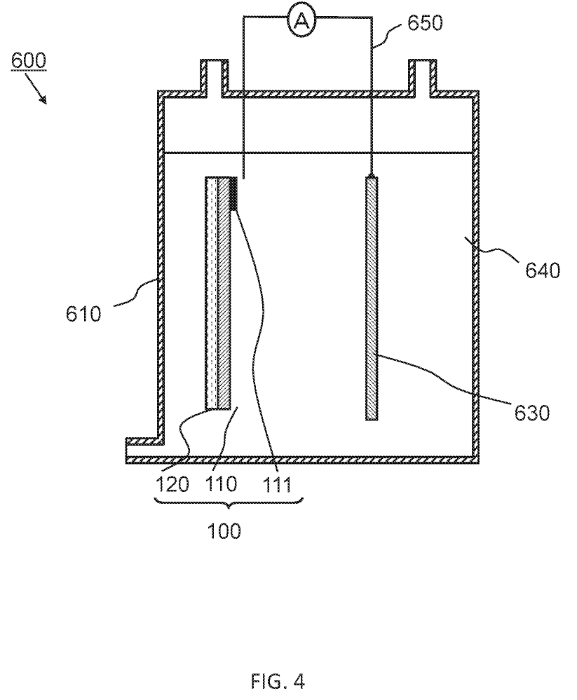

FIG. 4 shows a cross-sectional view of a hydrogen generation device 600 comprising the semiconductor photoelectrode 100. In the present embodiment, the semiconductor photoelectrode 100 comprises the strontium niobium oxynitride film 120. The strontium niobium oxynitride is a photosemiconductor and can be used as a photocatalyst. The hydrogen generation device shown in FIG. 4 comprises the semiconductor photoelectrode 100, a counter electrode 630, a liquid 640, and a container 610. As described above, the semiconductor photoelectrode 100 comprises the substrate 110 and the strontium niobium oxynitride film 120 grown on the substrate 110.

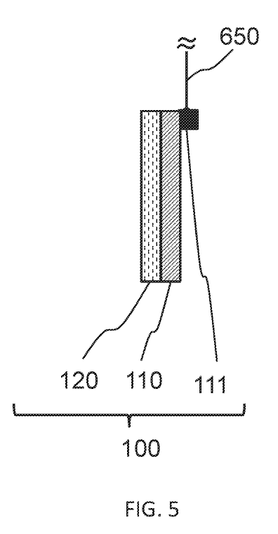

FIG. 5 shows a cross-sectional view of the semiconductor photoelectrode 100. The strontium titanate substrate 110 doped with niobium or lanthanum may be used. The strontium titanate substrate 110 doped with niobium or lanthanum is electrically conductive. As shown in FIG. 5, an ohmic electrode 111 may be formed on the conductive strontium titanate substrate 110. The ohmic electrode 111 is electrically connected to a conducting wire 650. The substrate 110 is a perovskite (e.g., a perovskite oxide).

It is desirable that the counter electrode 630 is formed of a material having a small overvoltage on the hydrogen generation reaction. Alternatively, it is desirable that the counter electrode 630 may be formed of a semiconductor photoelectrode capable of generating hydrogen. In particular, an example of the material of the counter electrode 630 is platinum, gold, silver, nickel, ruthenium oxide represented by the chemical formula RuO₂, iridium oxide represented by the chemical formula IrO₂, or a p-type semiconductor. Two or more materials may be used for the counter electrode 630.

The liquid 640 is water or an electrolyte aqueous solution. The electrolyte aqueous solution is acidic or alkaline. An example of the electrolyte aqueous solution is a sulfuric acid aqueous solution, a sodium sulfate aqueous solution, a sodium carbonate aqueous solution, a phosphate buffer solution, or a borate buffer solution. The liquid 640 may be constantly stored in the container 610 or may be supplied only in use.

The container 610 contains the semiconductor photoelectrode 100, the counter electrode 630, and the liquid 640. It is desirable that the container 610 is transparent. In particular, it is desirable that at least a part of the container 610 is transparent so that light can travel from the outside of the container 610 to the inside of the container 610. A user of the hydrogen generation device 600 prepares such a hydrogen generation device 600.

When the strontium niobium oxynitride film 120 is irradiated with light, oxygen is generated on the surface of the strontium niobium oxynitride film 120. Light such as sunlight travels through the container 610 and reaches the strontium niobium oxynitride film 120. Electrons and holes are generated respectively in the conduction band and valence band of the part of the strontium niobium oxynitride film 120 in which the light has been absorbed. Since the strontium niobium oxynitride film 120 is an n-type semiconductor, the holes migrate to the surface of the strontium niobium oxynitride film 120.

Water is split on the surface of the strontium niobium oxynitride film 120 as shown in the following reaction formula (1) to generate oxygen. On the other hand, electrons migrate from the strontium niobium oxynitride film 120 to the counter electrode 630 through the conducting wire 650. Hydrogen is generated as shown in the following reaction formula (2) on the surface of the counter electrode 630.

4h⁺+2H₂O→O₂↑+4H⁺ (1)
(h⁺ represents a hole)

4e⁻+4H⁺→2H₂↑ (2)

There is a depletion layer having a band bending on a solid-liquid interface formed on the surface of the strontium niobium oxynitride film 120. Theoretically, a depletion layer extends with a decrease in carrier density. Therefore, in a case where carrier density is low, electrons and holes generated in the conduction band and the valence band respectively are easily separated due to the internal electric field of the depletion layer. Since the semiconductor photoelectrode 100 according to the embodiment has low carrier density of less than 1.0×10¹⁸ cm⁻³, a hydrogen generation device comprising the semiconductor photoelectrode 100 according to the embodiment has high hydrogen generation efficiency.

### EXAMPLES

Hereinafter, the present invention will be described in more detail with reference to the following examples.

### Inventive Example 1

In the inventive example 1, a semiconductor photoelectrode 100 shown in FIG. 1 was fabricated as below.

First, a strontium niobium oxynitride film 120 having a thickness of 100 nanometers was grown by a reactive sputtering method on a perovskite strontium titanate substrate 110 having a (001) orientation only. In the reactive sputtering method, the temperature of the strontium titanate substrate 110 was maintained at 650 degrees Celsius. The material of the sputtering target was strontium niobate represented by the chemical formula Sr₂Nb₂O₇. The sputtering was carried out in an atmosphere of a mixture of argon, oxygen, and nitrogen. The total pressure in the chamber used for the sputtering was 0.5 Pa. The flow rate of argon was 5 sccm. The flow rate of oxygen was 0.05 sccm. The flow rate of nitrogen was 10 sccm. In this way, the strontium niobium oxynitride film 120 was grown epitaxially.

Then, the carrier density of the strontium niobium oxynitride film 120 was calculated through the Hall effect measurement based on the Van der Pauw method. As a result, the strontium niobium oxynitride film 120 according to the inventive example 1 had carrier density of 5.5×10¹⁵ cm⁻³.

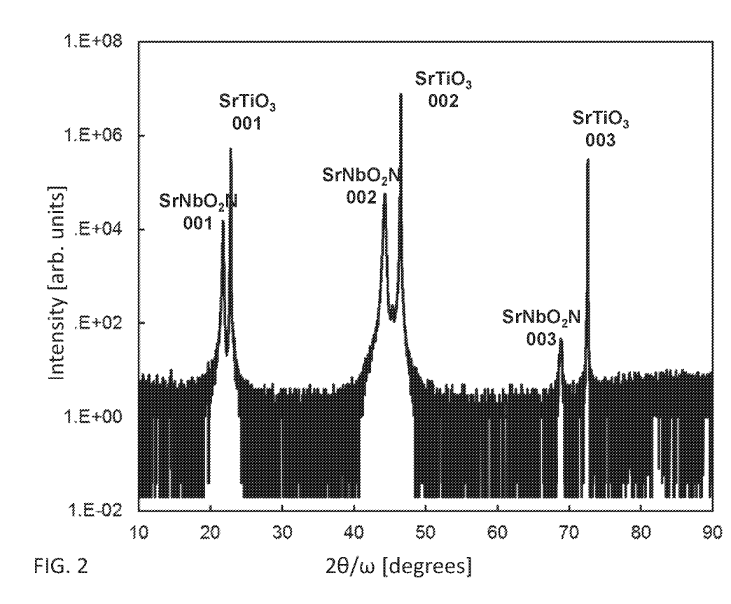

The semiconductor photoelectrode 100 was subjected to an X-ray diffraction analysis. FIG. 2 shows the result. As is clear from FIG. 2, six peaks were observed. Among them, three peaks are derived from a (001) plane, a (002) plane, and a (003) plane of the SrTiO₃. Other three peaks are derived from a (001) plane, a (002) plane, and a (003) plane of SrNbO₂N. As just described, only peaks of (00h) planes of SrNbO₂N were observed. This means that a strontium niobium oxynitride film having a (001) orientation only was formed on the strontium titanate substrate 110 having a (001) plane orientation.

### Inventive Example 2

In the inventive example 2, the semiconductor photoelectrode 100 shown in FIG. 1 was fabricated as below. The main difference from the inventive example 1 is that the atmosphere of the sputtering did not contain oxygen.

First, a strontium niobium oxynitride film 120 having a thickness of 100 nanometers was grown by a reactive sputtering method on a perovskite strontium titanate substrate 110 having a (001) orientation only. In the reactive sputtering method, the temperature of the strontium titanate substrate 110 was maintained at 650 degrees Celsius. The material of the sputtering target was strontium niobate represented by the chemical formula Sr₂Nb₂O₇. The sputtering was carried out in an atmosphere of a mixture of argon and nitrogen. The total pressure in the chamber used for the sputtering was 0.5 Pa. The flow rate of argon was 5 sccm. The flow rate of nitrogen was 10 sccm. In this way, the strontium niobium oxynitride film 120 was grown.

Then, the carrier density of the strontium niobium oxynitride film 120 was calculated through the Hall effect measurement based on the Van der Pauw method. As a result, the strontium niobium oxynitride film 120 according to the inventive example 2 had carrier density of 1.7×10¹⁷ cm⁻³.

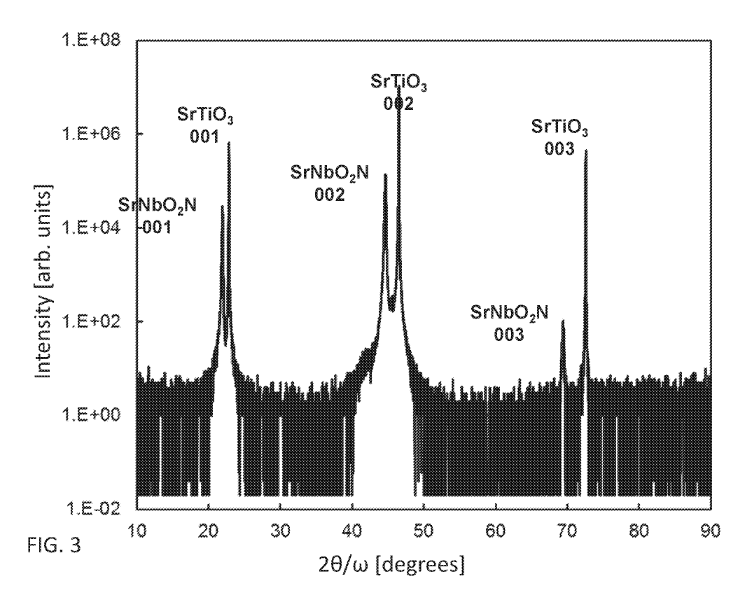

The semiconductor photoelectrode 100 was subjected to an X-ray diffraction analysis. FIG. 3 shows the result. As is clear from FIG. 3, six peaks were observed. Among them, three peaks are derived from a (001) plane, a (002) plane, and a (003) plane of the SrTiO₃. Other three peaks are derived from a (001) plane, a (002) plane, and a (003) plane of SrNbO₂N. As just described, only peaks of (00h) planes of SrNbO₂N were observed. This means that a strontium niobium oxynitride film having a (001) orientation only was formed on the strontium titanate substrate 110 having a (001) plane orientation.

The following Table 1 shows the results of the inventive examples 1-2.

TABLE 1

| | |
|---|---|
| Inventive | Inventive |
| example 1 | example 2 |

| | |
|---|---|
| Substrate | SrTiO₃ substrate |
| | having a (001) orientation only |

| | | |
|---|---|---|
| Growth temperature (Celsius) | 650 | 650 |
| Film thickness (nanometer) | 100 | 100 |
| Argon flow rate (sccm) | 5 | 5 |
| Oxygen flow rate (sccm) | 0.05 | 0 |
| Nitrogen flow rate (sccm) | 10 | 10 |
| Orientation | (001) only | (001) only |
| Carrier density (cm⁻³) | 5.5 × 10¹⁵ | 1.7 × 10¹⁷ |

### Inventive Example 3

In the inventive example 3, an experiment similar to the inventive example 1 was conducted, except that the perovskite strontium titanate substrate 110 has not a (001) orientation only, but a (110) orientation only.

### Inventive Example 4

In the inventive example 4, an experiment similar to the inventive example 1 was conducted, except that the perovskite strontium titanate substrate 110 has not a (001) orientation only, but a (111) orientation only.

The following Table 2 shows the results of the inventive examples 3-4.

TABLE 2

| | Inventive | Inventive |
|---|---|---|
| | example 3 | example 4 |
| Substrate | SrTiO₃ substrate | SrTiO₃ substrate |
| | having a (110) | having a (111) |
| | orientation only | orientation only |
| Growth temperature (Celsius) | 650 | 650 |
| Film thickness (nanometer) | 100 | 100 |
| Argon flow rate (sccm) | 5 | 5 |
| Oxygen flow rate (sccm) | 0.05 | 0.05 |
| Nitrogen flow rate (sccm) | 10 | 10 |
| Orientation | (110) only | (111) only |
| Carrier density (cm⁻³) | 2.1 × 10¹⁵ | 1.8 × 10¹⁵ |

### INDUSTRIAL APPLICABILITY

The strontium niobium oxynitride film according to the present invention can be used as a semiconductor photoelectrode used in a hydrogen generation device for generating hydrogen through light irradiation.

### REFERENTIAL SIGNS LIST

100 Semiconductor photoelectrode
110 Strontium titanate substrate
111 Ohmic electrode
120 Strontium niobium oxynitride film
600 Hydrogen generation device
610 Container
630 Counter electrode
640 Liquid
650 Conducting wire

### CONCLUSION

The inventions derived from the above disclosure will be listed below.
1. A method for growing a strontium niobium oxynitride film, the method comprising:

(a) growing, on a strontium titanate substrate, by a sputtering method, the strontium niobium oxynitride film having carrier density of not more than 1×10¹³ cm⁻³.
2. The method according to Item 1, wherein

a target used in the sputtering method is formed of strontium niobate; and

the strontium niobium oxynitride film is grown in an atmosphere containing nitrogen.
3. The method according to Item 2, wherein

the strontium niobate is represented by the chemical formula Sr₂Nb₂O₇.
4. The method according to Item 2, wherein

the atmosphere further contains oxygen.
5. The method according to Item 2, wherein

the atmosphere further contains argon.
6. The method according to Item 4, wherein

the atmosphere further contains argon.
7. The method according to Item 1, wherein

the strontium titanate substrate has a single orientation plane; and

the strontium niobium oxynitride film has a single orientation plane.
8. The method according to Item 7, wherein

the single orientation plane of the strontium titanate substrate is an orientation plane of a (001) plane; and

the single orientation plane of the strontium niobium oxynitride film is an orientation plane of a (001) plane.
9. The method according to Item 7, wherein

the single orientation plane of the strontium titanate substrate is an orientation plane of a (110) plane; and

the single orientation plane of the strontium niobium oxynitride film is an orientation plane of a (110) plane.
10. The method according to Item 7, wherein

the single orientation plane of the strontium titanate substrate is an orientation plane of a (111) plane; and

the single orientation plane of the strontium niobium oxynitride film is an orientation plane of a (111) plane.
11. The method according to Item 1, wherein

the strontium titanate substrate is doped with at least one selected from the group consisting of niobium and lanthanum.
12. A strontium niobium oxynitride having carrier density of not more than 1×10¹⁸ cm⁻³.
13. The strontium niobium oxynitride according to Item 12, wherein

the carrier density is not more than 1×10¹⁷ cm⁻³.
14. A strontium niobium oxynitride film having carrier density of not more than 1×10¹⁸ cm⁻³.
15. The strontium niobium oxynitride film according to Item 14, wherein

the carrier density is not more than 1×10¹⁷ cm⁻³.
16. The strontium niobium oxynitride film according to Item 14, wherein

the strontium niobium oxynitride film has a single orientation plane.
17. The strontium niobium oxynitride film according to Item 16, wherein

the single orientation plane is an orientation plane of a (001) plane.
18. The strontium niobium oxynitride film according to Item 16, wherein

the single orientation plane is an orientation plane of a (110) plane.
19. The strontium niobium oxynitride film according to Item 16, wherein

the single orientation plane is an orientation plane of a (111) plane.
20. A semiconductor photoelectrode comprising:

a strontium titanate substrate; and

a strontium niobium oxynitride film grown on the strontium titanate substrate,

wherein

the strontium niobium oxynitride film has carrier density of not more than 1×10¹⁸ cm⁻³.
21. The semiconductor photoelectrode according to Item 20, wherein

the carrier density is not more than 1×10¹⁷ cm⁻³.
22. The semiconductor photoelectrode according to Item 20, wherein

the strontium titanate substrate has a single orientation plane; and

the strontium niobium oxynitride film has a single orientation plane.
23. The semiconductor photoelectrode according to Item 22, wherein

the single orientation plane of the strontium titanate substrate is an orientation plane of a (001) plane; and

the single orientation plane of the strontium niobium oxynitride film is an orientation plane of a (001) plane.
24. The semiconductor photoelectrode according to Item 22, wherein

the single orientation plane of the strontium titanate substrate is an orientation plane of a (110) plane; and

the single orientation plane of the strontium niobium oxynitride film is an orientation plane of a (110) plane.
25 The semiconductor photoelectrode according to Item 22, wherein

the single orientation plane of the strontium titanate substrate is an orientation plane of a (111) plane; and

the single orientation plane of the strontium niobium oxynitride film is an orientation plane of a (111) plane.
26. The semiconductor photoelectrode according to Item 20, wherein

the strontium titanate substrate is doped with at least one selected from the group consisting of niobium and lanthanum.
27. A hydrogen generation device, comprising:

a semiconductor photoelectrode according to Item 20;

a counter electrode electrically connected to the semiconductor photoelectrode;

a liquid in contact with the strontium niobium oxynitride film and the counter electrode; and

a container containing the semiconductor photoelectrode, the counter electrode, and the liquid, wherein

the liquid is water or an electrolyte aqueous solution; and

hydrogen is generated on a surface of the counter electrode when the strontium niobium oxynitride film is irradiated with light.
28. The hydrogen generation device according to Item 27, wherein

the carrier density is not more than 1×10¹⁷ cm⁻³.
29. The hydrogen generation device according to Item 27, wherein

the strontium titanate substrate has a single orientation plane; and

the strontium niobium oxynitride film has a single orientation plane.
30. The hydrogen generation device according to Item 29, wherein

the single orientation plane of the strontium titanate substrate is an orientation plane of a (001) plane; and

the single orientation plane of the strontium niobium oxynitride film is an orientation plane of a (001) plane.
31. The hydrogen generation device according to Item 29, wherein

the single orientation plane of the strontium titanate substrate is an orientation plane of a (110) plane; and

the single orientation plane of the strontium niobium oxynitride film is an orientation plane of a (110) plane.
32. The hydrogen generation device according to Item 29, wherein

the single orientation plane of the strontium titanate substrate is an orientation plane of a (111) plane; and

the single orientation plane of the strontium niobium oxynitride film is an orientation plane of a (111) plane.
33. The hydrogen generation device according to Item 27, wherein

the strontium titanate substrate is doped with at least one selected from the group consisting of niobium and lanthanum.
34. A method for generating hydrogen, comprising:

(a) preparing a hydrogen generation device, comprising:

a semiconductor photoelectrode according to claim 16;

a counter electrode electrically connected to the semiconductor photoelectrode;

a liquid in contact with the strontium niobium oxynitride film and the counter electrode; and

a container containing the semiconductor photoelectrode, the counter electrode, and the liquid,

wherein

the liquid is water or an electrolyte aqueous solution; and

(b) irradiating the strontium niobium oxynitride film with light to generate hydrogen on a surface of the counter electrode.
35. The method according to Item 34. wherein

the carrier density is not more than 1×10¹⁷ cm⁻³.
36. The method according to Item 34, wherein

the strontium titanate substrate has a single orientation plane; and

the strontium niobium oxynitride film has a single orientation plane.
37. The method according to Item 36, wherein

the single orientation plane of the strontium titanate substrate is an orientation plane of a (001) plane; and

the single orientation plane of the strontium niobium oxynitride film is an orientation plane of a (001) plane.
38. The method according to Item 36, wherein

the single orientation plane of the strontium titanate substrate is an orientation plane of a (110) plane; and

the single orientation plane of the strontium niobium oxynitride film is an orientation plane of a (110) plane.
39. The method according to Item 36, wherein

the single orientation plane of the strontium titanate substrate is an orientation plane of a (111) plane; and

the single orientation plane of the strontium niobium oxynitride film is an orientation plane of a (111) plane.
40. The method according to Item 34, wherein

the strontium titanate substrate is doped with at least one selected from the group consisting of niobium and lanthanum.

1. A method for growing a strontium niobium oxynitride film, the method comprising:
(a) growing, on a strontium titanate substrate, by a sputtering method, the strontium niobium oxynitride film having carrier density of not more than 1×10¹⁸ cm⁻³.

2. The method according to claim 1, wherein
a target used in the sputtering method is formed of strontium niobate; and
the strontium niobium oxynitride film is grown in an atmosphere containing nitrogen.

3. The method according to claim 2, wherein
the strontium niobate is represented by the chemical formula Sr₂Nb₂O₇.

4. The method according to claim 2, wherein
the atmosphere further contains oxygen.

5. The method according to claim 2, wherein
the atmosphere further contains argon.

6. The method according to claim 4, wherein
the atmosphere further contains argon.

7. The method according to claim 1, wherein
the strontium titanate substrate has a single orientation plane; and
the strontium niobium oxynitride film has a single orientation plane.

8. The method according to claim 7, wherein
the single orientation plane of the strontium titanate substrate is an orientation plane of a (001) plane; and
the single orientation plane of the strontium niobium oxynitride film is an orientation plane of a (001) plane.

9. The method according to claim 7, wherein
the single orientation plane of the strontium titanate substrate is an orientation plane of a (110) plane; and
the single orientation plane of the strontium niobium oxynitride film is an orientation plane of a (110) plane.

10. The method according to claim 7, wherein
the single orientation plane of the strontium titanate substrate is an orientation plane of a (111) plane; and
the single orientation plane of the strontium niobium oxynitride film is an orientation plane of a (111) plane.

11. The method according to claim 1, wherein
the strontium titanate substrate is doped with at least one selected from the group consisting of niobium and lanthanum.

12. A strontium niobium oxynitride having carrier density of not more than 1×10¹⁸ cm⁻³.

13. The strontium niobium oxynitride according to claim 12, wherein
the carrier density is not more than 1×10¹⁷ cm⁻³.

14. A strontium niobium oxynitride film having carrier density of not more than 1×10¹⁸ cm⁻³.

15. The strontium niobium oxynitride film according to claim 14, wherein
the carrier density is not more than 1×10¹⁷ cm⁻³.

16. The strontium niobium oxynitride film according to claim 14, wherein
the strontium niobium oxynitride film has a single orientation plane.

17. The strontium niobium oxynitride film according to claim 16, wherein
the single orientation plane is an orientation plane of a (001) plane.

18. The strontium niobium oxynitride film according to claim 16, wherein
the single orientation plane is an orientation plane of a (110) plane.

19. The strontium niobium oxynitride film according to claim 16, wherein
the single orientation plane is an orientation plane of a (111) plane.

20. A semiconductor photoelectrode comprising:
a strontium titanate substrate; and
a strontium niobium oxynitride film grown on the strontium titanate substrate,
wherein
the strontium niobium oxynitride film has carrier density of not more than 1×10¹⁸ cm⁻³.

21. The semiconductor photoelectrode according to claim 20, wherein
the carrier density is not more than 1×10¹⁷ cm⁻³.

22. The semiconductor photoelectrode according to claim 20, wherein
the strontium titanate substrate has a single orientation plane; and
the strontium niobium oxynitride film has a single orientation plane.

23. The semiconductor photoelectrode according to claim 20, wherein
the strontium titanate substrate is doped with at least one selected from the group consisting of niobium and lanthanum.

24. A hydrogen generation device, comprising:
a semiconductor photoelectrode according to claim 20;
a counter electrode electrically connected to the semiconductor photoelectrode;
a liquid in contact with the strontium niobium oxynitride film and the counter electrode; and
a container containing the semiconductor photoelectrode, the counter electrode, and the liquid, wherein
the liquid is water or an electrolyte aqueous solution; and
hydrogen is generated on a surface of the counter electrode when the strontium niobium oxynitride film is irradiated with light.

25. The hydrogen generation device according to claim 24, wherein
the carrier density is not more than 1×10¹⁷ cm⁻³.

26. The hydrogen generation device according to claim 24, wherein
the strontium titanate substrate has a single orientation plane; and
the strontium niobium oxynitride film has a single orientation plane.

27. The hydrogen generation device according to claim 26, wherein
the strontium titanate substrate is doped with at least one selected from the group consisting of niobium and lanthanum.
